(19) United States
(12) Patent Application Publication
(10) Pub. No.: US 2014/0374684 A1
(43) Pub. Date: Dec. 25, 2014

(54) VARIABLE RESISTANCE MEMORY DEVICE AND METHOD OF MANUFACTURING THE SAME

(71) Applicant: SK hynix Inc., Gyeonggi-do (KR)

(72) Inventors: Ha Chang JUNG, Gyeonggi-do (KR); Eun Hyup LEE, Gyeonggi-do (KR)

(73) Assignee: SK hynix Inc., Gyeonggi-do (KR)

(21) Appl. No.: 14/046,549

(22) Filed: Oct. 4, 2013

(30) Foreign Application Priority Data
Jun. 21, 2013 (KR) 10-2013-0071497

(51) Int. Cl. H01L 45/00

(52) U.S. Cl. CPC H01L 45/1233; H01L 45/1683
USPC 257/3; 438/382

(57) ABSTRACT

A variable resistance memory device and a method of manufacturing the same are provided. The variable resistance memory device includes a multi-layered insulating layer formed on a semiconductor substrate on which a lower electrode is formed, and including a plurality of holes of which diameters are increased at a first height or higher, a variable resistance material layer formed on the lower electrode to a second height of each of the holes, and an upper electrode formed on the variable resistance material layer to be buried in each of the holes.

### CROSS-REFERENCES TO RELATED APPLICATION

This application claims priority under 35 U.S.C. 119(a) to Korean application number 10-2013-0071497, filed on Jun. 21, 2013, in the Korean Patent Office, which is incorporated by reference in its entirety.

### BACKGROUND OF THE INVENTION

1. Technical Field

Various implements of the inventive concept relate to a nonvolatile memory device, and more particularly, to a variable resistance memory device and a method of manufacturing the same.

2. Related Art

In recent years, semiconductor devices that exhibit high performance while consuming low power have been demanded. According to this demand, next-generation non-volatile semiconductor memory devices of which refreshes are unnecessary have been researched. Typical examples of the next-generation non-volatile semiconductor memory devices are variable resistance memory devices, For example, the variable resistance memory devices include phase-change random access memory devices (PCRAMs), resistive RAMs (ReRAMs), magnetic RAMs (MRAMs), spin-transfer torque magnetoresistive RAMs (STTMRAMs), and polymer RAMs (PoRAMs).

The variable resistance memory devices perform a memory operation to have a set state or a reset state by controlling a phase-change material that constitutes a data storage unit to have a crystalline state or an amorphous state, respectively.

Attempts to reduce a reset current, that is, a current required to switch a phase-change material to an amorphous state in the variable resistance memory devices, have been made. More specifically, to reduce the reset current in the variable resistance memory devices, attempts to reduce a contact area between the lower electrode and a data storage unit have been made increasingly.

In recent years, due to high integration of the variable resistance memory devices, cell shrinkage has been progressed to prevent interference between data storage units of cells, that is, disturbance. However, there is a limitation to ensure a sufficient overlay margin between the data storage unit and an upper electrode if a current process is used.

### SUMMARY

Various exemplary embodiments of the present invention are directed to a variable resistance memory device that may reduce a reset current, and a method of manufacturing the same.

According to one aspect of an exemplary embodiment of the present invention, there is provided a variable resistance memory device. The variable resistance memory device may include a multi-layered insulating layer formed on a semiconductor substrate on which a lower electrode is formed, and including a plurality of holes of which diameters are increased at a first height or higher, a variable resistance material layer formed on the lower electrode to a second height of each of the holes, and an upper electrode formed on the variable resistance material layer to be buried in each of the holes.

According to an aspect of another exemplary embodiment, there is provided a method of manufacturing a variable resistance memory device. The method may include forming the lower electrode on a semiconductor substrate, forming a first insulating layer on the lower electrode, forming a second insulating layer having a hole on the first insulating layer, forming a first spacer and a second spacer on a side call of the hole; forming an extended hole that extends from the hole formed in the second insulating layer to the first insulating layer, to expose a portion of an upper surface of the lower electrode, forming a variable resistance material layer on the lower electrode, in the extended hole, to a first height of the extended hole, and forming an upper electrode on the variable resistance material layer to be buried in the hole.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more dearly understood from the following detailed description taken in conjunction with the accompanying drawings, in which:

FIG. 1 is a cross-sectional view illustrating a structure of a variable resistance memory device according to an embodiment of the inventive concept; and

FIGS. 2A to 2H are cross-sectional views illustrating a method of manufacturing a variable resistance memory device according to an embodiment of the inventive concept.

### DETAILED DESCRIPTION

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present. In addition, a singular form may include a plural form as long as it is not specifically mentioned in a sentence.

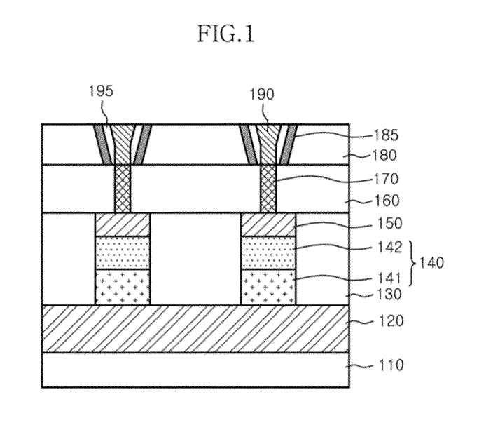

FIG. 1 is a cross-sectional view illustrating a structure of a variable resistance memory device according to an embodiment of the inventive concept.

As illustrated in FIG. 1, a variable resistance memory device according to an embodiment of the inventive concept may include an N³⁰ type base region 120 formed on the semiconductor substrate 110. A first interlayer insulating layer 130 is formed on the N³⁰ type base region 120 and includes a plurality of holes. A switching device 140 including an N type region 141 and a P type region 142 is formed in each of the holes formed in the first interlayer insulating layer 130. A lower electrode 150 is formed on the switching device 140, in each of the holes formed in the first interlayer insulating layer 130. A second interlayer insulating layer 160 including a plurality of holes is formed on the first interlayer insulating layer 130 in which the switching device 140 and the lower electrode 150 are formed. Each of the holes formed in the second interlayer insulating layer 160 has a smaller diameter than each of the holes formed in the first interlayer insulating layer 130. A variable resistance material layer 170 is formed in the each of the holes formed in the second interlayer insulating layer 160. A third interlayer insulating layer 180 including a plurality of holes is formed on the second interlayer insulating layer 160 in which the variable resistance material layer 170 is formed. Each of the holes formed in the third interlayer insulating layer 180 is formed to have a shape in which a diameter of each of the holes in the third interlayer insulating layer 180 is substantially the same as a diameter of each of the holes formed in the second interlayer insulating layer 160 for a portion from an upper surface of the second interlayer insulating layer 160 to a predetermined height, that is, about a ⅓ height of the third interlayer insulating layer 180. The diameter of each of the holes in the third interlayer insulating layer 180 is increased from the predetermined height toward an upper surface of the third interlayer insulating layer 180. An upper electrode 190 is formed in each of the holes formed in the third interlayer insulating layer 180. The reference numerals 185 and 195 are a first spacer and a second spacer, respectively, and the first spacer 185 and the second spacer 195 may be formed to prevent disturbance between cells. In FIG. 1, a PN diode including the N type region 141 and the P type region 142 has illustrated as the switching device 140, but the switching device 140 is not limited thereto. The switching device 140 may be a shottky diode or a MOS transistor other than the diode.

The diameter of the hole formed in the second interlayer insulating layer 160 is formed to be smaller than that of the hole formed in the first interlayer insulating layer 130 to reduce an contact area between the lower electrode 150 and the variable resistance material layer 170, and thus to reduce a reset current.

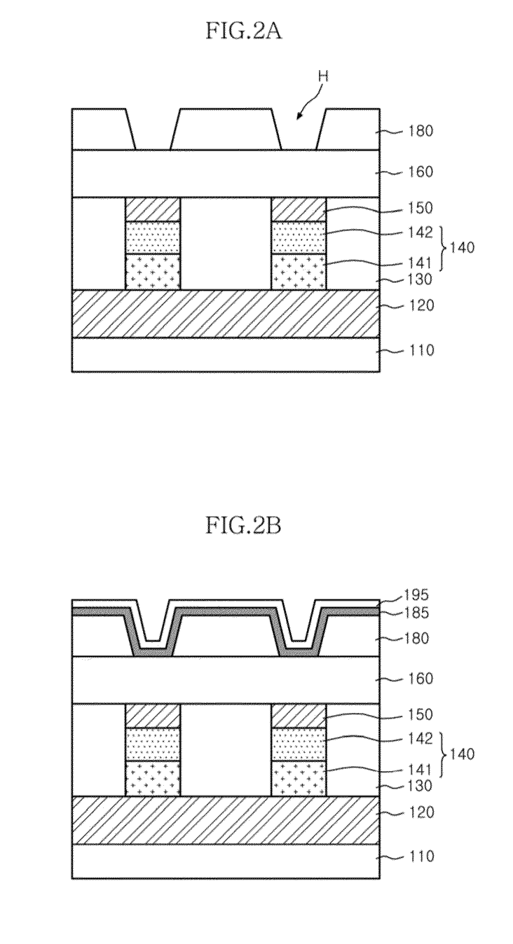

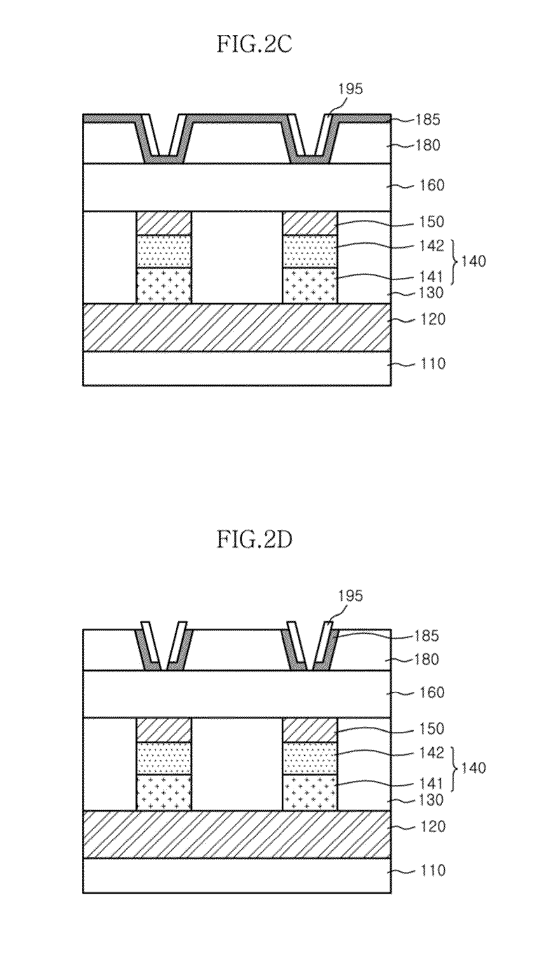

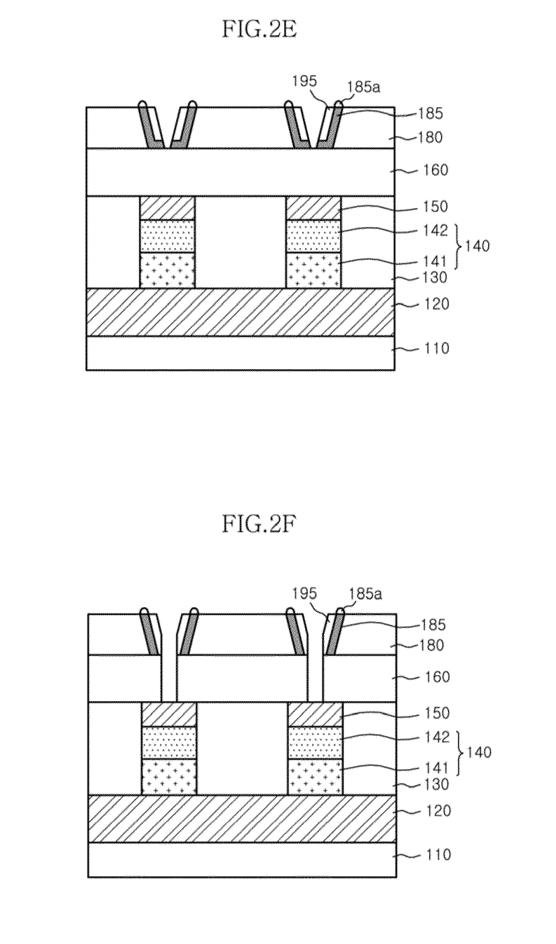

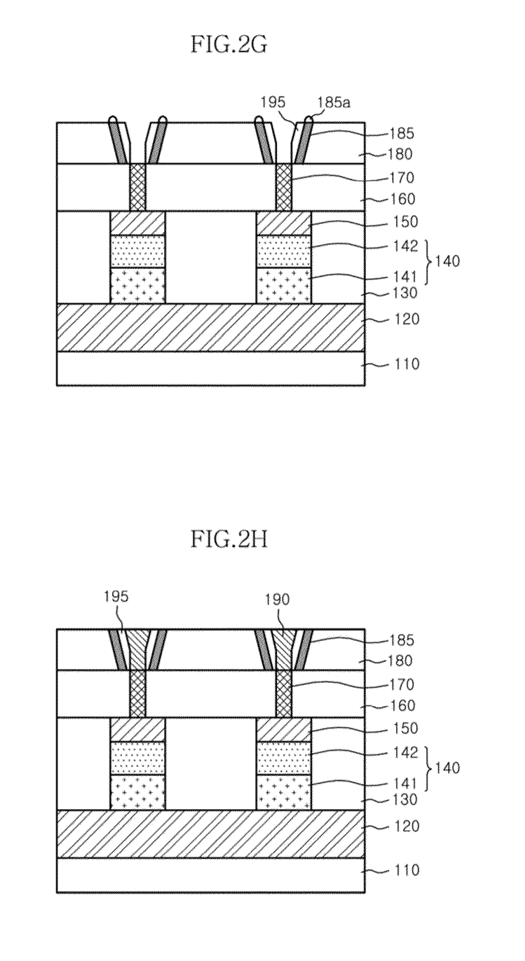

A method of manufacturing the variable resistance memory device having the structure according to an embodiment of the inventive concept will be described in detail with reference to FIGS. 2A to 2H.

FIGS. 2A to 2H are cross-sectional views illustrating a method of manufacturing a variable resistance memory device according to an embodiment of the inventive concept.

As illustrated in FIG. 2A, a method of manufacturing a variable resistance memory device according to an embodiment of the inventive concept includes providing a semiconductor substrate 110, and forming an N⁺ type base region 120 serving as a word line by implanting N type impurities into an upper portion of the provided semiconductor substrate 110. A first interlayer insulating layer 130 including a hole is formed on the N⁺ type base region 120, a switching device 140 including an N type region 141 and a P type region 142 is formed in the hole, and a lower electrode 150 is formed on the switching device 140, in the hole.

A second interlayer insulating layer 160 and a third interlayer insulating layer 180 are deposited on the first interlayer insulating layer 130 in which the switching device 140 and the lower electrode 150 are formed, A plurality of holes H are formed in the third interlayer insulating layer 180 through a photolithographic process so that each of the holes H is formed in a location corresponding to a location in which the lower electrode 150 is formed. The hole H formed in the third interlayer insulating layer 180 may be formed to have a slope so that a diameter in a lower portion of the hole H is smaller than that in an upper portion thereof. The slope of the hole H may be in a range of 80 degrees to 90 degrees. Forming the hole H having the slope may lead to easy formation of a spacer. Further, the second interlayer insulating layer 160 and the third interlayer insulating layer 180 may be formed of materials having different etch characteristics. For example, the second interlayer insulating layer 160 may include a nitride material, and the third interlayer insulating layer 180 may include an oxide material.

As illustrated in FIG. 2B a first spacer material 185 is deposited along a surface of the third interlayer insulating layer 180 and an inner surface of the hole H, and then a second spacer material 195 is deposited on the first spacer material 185. The first spacer material 185 may include the same material as the second interlayer insulating layer 160, for example, a nitride material, and the second spacer material 195 may include the same material as the third interlayer insulating layer 180, for example, an oxide material.

As illustrated in FIG. 2C, a portion of the second spacer material 195 is selectively etched to be left, for example, only on the inner sidewall of the hole H using a difference in etch selectivity between the first spacer material 185 and the second spacer material 195. To selectively etch the second spacer material 195, C₄F₆ in a range of 30 sccm to 100 sccm and C₃F₈ in a range of 30 sccm to 100 sccm are used. Oxygen (O₂) or argon (Ar) gas may be further injected to make the etching process easier to perform. material 185, that is, the first spacer material 185 deposited on an upper surface of the third interlayer insulating layer 180 and formed on a bottom of the hole H is selectively etched using the difference in etch selectivity between the first spacer material 185 and the second spacer material 195. To selectively etch the first spacer material 185, a combination of CH₃F and O₂ is used under pressure in a range of 3 mT to 90 mT. An etch selectivity of the first spacer material 185 to the second spacer material 195 may be ensured in a range of 10:1 to 40:1 in the etching process using the combination.

As illustrated in FIG. 2E, the first spacer material 185 and the second spacer material 195 are planarized to form a first spacer 185 and a second spacer 195, respectively. For example, only an upper surface of the first spacer 185 is selectively oxidized to form a first spacer oxide layer 185a. The first spacer oxide layer 185a may prevent the first spacer 185, which is formed of the same material as that of the second interlayer insulating layer 160, from being etched in a subsequent etching process of the second interlayer insulating layer 160.

As illustrated in FIG. 2F, the second interlayer insulating layer 160 is etched to expose a portion of an upper surface of the lower electrode 150, and thus a hole is patterned to pass through the second interlayer insulating layer 160 and the third interlayer insulating layer 180. To selectively etch the second interlayer insulating layer 160, a combination of CH₃F and O₂ is used under pressure in a range of 3 mT to 90 mT. The hole formed through the above-described process is formed to have a diameter smaller than that of the hole formed in the first interlayer insulating layer 130. The hole has a shape in which the diameter is constant from the upper surface of second interlayer insulating layer 160 to a specific height (for example, ⅓ height) of the third interlayer insulating layer 180, and increased from the specific height of the third interlayer insulating layer 180 toward an upper surface of the third interlayer insulating layer 180.

As illustrated in FIG. 2G a variable resistance material is deposited through an atomic layer deposition (ALD) method to be gap-filled in the hole formed passing through the second interlayer insulating layer 160 and the third interlayer insulating layer 180, and then etched to a height corresponding to a height of the second interlayer insulating layer 160 through an etch back process to form a variable resistance material layer 170. In FIG. 2G, the variable resistance material layer 170 is formed to correspond to the height of the second interlayer insulating layer 160, but this is not limited thereto. The variable resistance material layer 170 may be formed to a height just before the diameter of the hole in the third interlayer insulating layer 180 is increased. For example, the variable resistance material layer may include Ge₂Sb₂Te₅ (GST). When the variable resistance material is etched back, the variable resistance material may be etched, for example, only using Ar gas to prevent the second interlayer insulating layer 160 and the third interlayer insulating layer 180 from being damaged.

As illustrated in FIG. 2H, an upper electrode material is gap-filled to be buried in the hole in the variable resistance material layer 170 and then planarized to form an upper electrode 190. A first spacer oxide layer 185a is removed in the planarization process of forming the upper electrode 190.

The variable resistance memory device according to an embodiment of the inventive concept may reduce a contact area between the lower electrode 150 and the variable resistance material layer 170, and thus may reduce a reset current.

Further, the variable resistance memory device according to an embodiment of the inventive concept forms a hole passing through the second interlayer insulating layer 160 and the third interlayer insulating layer 180, and then forms the variable resistance material layer 170 and the upper electrode 190 in the hole, and thus may prevent an overlay issue between the variable resistance material layer 170 and the upper electrode 190.

The above embodiment of the present invention is illustrative and not !imitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A variable resistance memory device, comprising:
a multi-layered insulating layer formed on a semiconductor substrate on which a lower electrode is formed, and including a plurality of holes of which diameters are increased at a first height or higher;
a variable resistance material layer formed on the lower electrode to a second height of each of the holes; and
an upper electrode formed on the variable resistance material layer to be buried in each of the holes.

2. The variable resistance memory device of claim 1, wherein the multi-layered insulating layer includes:
a first insulating layer formed on the semiconductor substrate on which the lower electrode is formed and formed of a first material; and
a second insulating layer formed on the first insulating layer and formed of a second material having a different etch selectivity from the first material.

3. The variable resistance memory device of claim 2, further comprising:
a first spacer formed on a sidewall of each of the holes from the first height of each hole or higher; and
a second spacer formed on a side a of the first spacer.

4. The variable resistance memory device of claim 3, wherein the first spacer is formed of the same material as that of the second insulating layer and the second spacer is formed of the same material as that of the first insulating layer.

5. The variable resistance memory device of claim 4, wherein the first height is a ⅓ height of the second insulating layer from an upper surface of the second insulating layer.

6. The variable resistance memory device of claim 5, wherein the second height is between a height of the first insulating layer and the first height.

7. A method of manufacturing a variable resistance memory, device, comprising:
forming the lower electrode on a semiconductor substrate;
forming a first insulating layer on the lower electrode;
forming a second insulating layer having a hole, on the first insulating layer;
forming a first spacer and a second spacer on a sidewall of the hole
forming an extended hole that extends from the hole formed in the second insulating layer to the first insulating layer, to expose a portion of an upper surface of the lower electrode;
forming a variable resistance material layer on the lower electrode, in the extended hole, to a first height of the extended hole; and
forming an upper electrode on the variable resistance material layer to be buried in the hole.

8. The method of claim 7, wherein the first insulating layer and the second insulating layer are formed of materials having different etch selectivities from each other.

9. The method of claim 8, wherein an angle between the sidewall and a bottom of the hole formed in the second insulating layer is in a range of 80 degrees to 90 degrees.

10. The method of claim 9, wherein the forming of the first spacer and the second spacer is performed before the forming of the extended hole, and the forming of the first spacer and the second spacer includes:
forming a first spacer material along an upper surface of the second insulating layer and an inner surface of the hole;
forming a second spacer material on the first spacer material; and
selectively etching the second spacer material to be left only on a sidewall of the first spacer material, thereby forming the second spacer; and
selectively etching the first spacer material to be left only on the sidewall of the hole, thereby forming the first spacer.

11. The method of claim 10, wherein in the forming of the second spacer, C₄F₆ in a range of 30 sccm to 100 sccm and C₃F₈ in a range of 30 sccm to 100 sccm are used, and oxygen (O₂) or argon (Ar) gas is further injected to selectively etch the second spacer material.

12. The method of claim 10 wherein in the forming of the first spacer, a combination of CH₃F and O₂ is used under pressure in a range of 3 mT to 90 mT to selectively etch the first spacer material.

13. The method of claim 10, wherein the second spacer is formed of the same material as that of the second insulating layer and the first spacer is formed of the same material as that of the first insulating layer.

14. The method of claim 10, wherein the first height is between a height of the first insulating layer and a ⅔ height of the second insulating layer.

15. The method of claim 10, further comprising oxidizing an upper surface of the first spacer before the forming of the extended hole, wherein the oxidized upper surface of the first spacer is removed in the forming of the upper electrode.

16. A variable resistance memory device, comprising:
a lower electrode formed on a semiconductor substrate;
a multi-layered insulating layer formed on the lower electrode and including a hole that exposes a portion of an upper surface of the lower electrode, wherein a diameter of the hole is increased from a first height of the hole toward an upper surface of the multi-layered insulating layer;
a variable resistance material layer formed on the lower electrode, in the hole, to a second height of the hole; and
an upper electrode formed on the variable resistance mate layer to be buried in the hole.

17. The variable resistance memory device of claim 16, wherein the multi-layered insulating layer includes:
a first insulating layer formed on the lower electrode and including a first material; and
a second insulating layer formed on the first insulating layer and including a second material that has an etch selectivity different from that of the first material.

18. The variable resistance memory device of claim 17, wherein the first height of the hole is a ⅔ height of the second insulating layer.

19. The variable resistance memory device of claim 18, wherein the second height of the hole is between a height of the first insulating layer and the first height of the hole.

20. The variable resistance memory device of claim 19, further comprising:
a first spacer formed along a sidewall of the hole from the first height of the hole to the upper surface of the second insulating layer; and
a second spacer formed along a sidewall of the first spacer,
wherein the first spacer is formed of the same material as that of the second insulating layer and the second spacer is formed of the same material as that of the first insulating layer.
